(19) United States
(12) Patent Application Publication
(10) Pub. No.: US 2013/0146127 A1
(43) Pub. Date: Jun. 13, 2013

(54) FLOATATION DEVICE FOR SOLAR PANELS

(71) Applicants: Soren Yde Lunoe, Capertee (AU); Emanuel ,Hillel Szumer, Buderim (AU)

(72) Inventors: Soren Yde Lunoe, Capertee (AU); Emanuel ,Hillel Szumer, Buderim (AU)

(73) Assignee: C & L Pastoral Company Pty Ltd, Capertee ,NSW (AU)

(21) Appl. No.: 13/576,645

(22) PCT Filed: Feb. 2, 2011
(86) PCT No.: PCT/AU2011/000098

§ 371 Date: Nov. 6, 2012

(30) Foreign Application Priority Data
Feb. 2, 2010 (AU) 2010900401

(51) Int. Cl. B63B 35/00; H01L 31/042; B63B 39/03

(52) U.S. Cl. CPC B63B 35/00; B63B 39/03; H01L 31/0422
USPC 136/251; 114/264; 114/121

(57) ABSTRACT

There is provided a floatation device for supporting at least one photovoltaic solar panel above a body of water. Preferably, the floatation device includes a base that is able to float on or in the body of water, and at least one support to position the at least one photovoltaic solar panel at an angle to the base. At least one coupling member is used to couple the floatation device to an adjacent floatation device. In various embodiments an array of floatation devices holding solar panels can be constructed that can be rotated on the body of water to relatively easily track the motion of the sun across the sky during the day. The pitch angle of solar panels can be fixed or varied. Optionally, the base includes at least one opening.

### TECHNICAL FIELD

The present invention generally relates to frames, mounts or supports for photovoltaic solar panels. More particularly, the present invention relates to a floatation device that can be used as a frame, mount or support to enable a solar panel to be floated on or above a body of water.

### BACKGROUND

Photovoltaic solar panels are well known and convert electromagnetic radiation from the sun into electricity. This renewable energy source continues to attract a high level of interest in both research and commercial fields.

In use, photovoltaic solar panels are often mounted on a supporting frame. Conventional frames support solar panels above the ground and at an angle to an axis parallel to the ground (i.e. pitch angle). This often means that an array of solar panels has a fixed rotational orientation about an axis perpendicular to the ground (i.e. rotational angle). For improved efficiency, it can be primarily desirable to vary the rotational angle to track the motion of the sun during the day. It can be secondarily desirable to vary the pitch angle to track the height of the sun above the horizon during the year. However, relatively bulky or complex mechanisms are required to allow a ground-based array of solar panels to be rotated through variable rotational angles as a complete unit. The Applicant has identified that ground-based arrays of solar panels can have significant tracking problems due to the required complexity.

The Applicant has identified a need for a new or improved floatation device for supporting a solar panel above a body of water. The Applicant has also identified a need to reduce the evaporation rate from the surface of a body of water.

The reference in this specification to any prior publication (or information derived from the prior publication), or to any matter which is known, is not, and should not be taken as an acknowledgment or admission or any form of suggestion that the prior publication (or information derived from the prior publication) or known matter forms part of the common general knowledge in the field of endeavour to which this specification relates.

### BRIEF SUMMARY

In a general form there is provided a floatation device for supporting or mounting at least one photovoltaic solar panel above a body of water.

The angle of inclination (i.e. pitch angle) of the solar panel relative to the surface of the body of water can be fixed or variable in different embodiments. In one embodiment, the angle of inclination of the solar panel relative to the floatation device is variable. In another embodiment, the angle of inclination of the floatation device itself is variable relative to the surface the body of water.

In a particular example form there is provided a floatation device for supporting at least one photovoltaic solar panel above a body of water, comprising: a base, integrally formed as a section including at least one opening, able to float on the body of water; at least one support to position the at least one photovoltaic solar panel at an angle to the base; and, at least one coupling member to couple the floatation device to an adjacent floatation device.

In another particular example form there is provided a floatation device for supporting at least one photovoltaic solar panel above a body of water, comprising: a base able to float on the body of water; at least one support to position the at least one photovoltaic solar panel at an angle to the base; and, a coupling member, formed as a recess within the base, used to couple the floatation device to an adjacent floatation device.

In a particular embodiment the base includes a hollow body or shell, and/or the hollow body or shell is filled with a buoyant material. In another particular embodiment the base includes at least one opening. In a further particular embodiment the at least one solar panel is positioned above and away from the at least one opening. In a further particular embodiment the base includes a first opening and a second opening.

In a particular embodiment the at least one support is a protrusion extending from a surface of the base and having a support surface that is positioned at an angle in relation to the surface of the base. In a further particular embodiment the at least one solar panel is fixed to the support surface. In a further particular embodiment the at least one support is a rigid and the angle is fixed. In a further particular embodiment the at least one support allows the support surface to be rotated to change the angle.

According to another example form there are two supports spaced apart for supporting a photovoltaic solar panel. According to yet another example form there are three supports being a first end support positioned near an edge of the base, a second end support positioned near an opposite edge of the base, and a middle support positioned between the first opening and the second opening.

In a particular embodiment the device includes a ballast tank or container operable to adjust a base angle of a surface of the base relative to the surface of the body of water. In this form, air and/or liquid can be input/released from the ballast tank or container to adjust the base angle (i.e. the angle of inclination of the floatation device itself is variable relative to the surface the body of water) and hence the pitch angle of the at least one solar panel.

According to other various optional embodiments: the at least one coupling member is a recess provided in the base; the at least one coupling member is a projection provided as part of the base; the at least one coupling member is a linkage member received by recesses in adjacent bases; the recess is able to couple with a projection of the adjacent floatation device and/or the linkage member to form a joint; and/or the projection is able to couple with a recess of the adjacent floatation device to form a joint.

According to still other various optional embodiments: the at least one coupling member is a mortice provided in the base; the at least one coupling member is a tenon provided as part of the base; the at least one coupling member is a dog bone member; and/or there is provided a plurality of coupling members including a first mortice, a second mortice, a first tenon and a second tenon.

In another optional form a first solar panel and an adjacent second solar panel are supported by the at least one support. In yet another optional form an array of floatation devices is formed by coupling a plurality of floatation devices together.

According to another optional form the base includes at least one anchor point to attach a cable. In yet another optional form applying a force to the cable causes rotation of the floatation device on the body of water.

In other optional forms, a tank is operable to adjust a pitch angle relative to the base; air is input/released from the tank to adjust the pitch angle; the tank is able to move within and extend through at least one opening in the base; and/or the tank is connected to or forms part of a frame that supports the at least one solar panel.

According to another optional form, one or more struts are provided to set a pitch angle, and the one or more struts may be collapsible. According to yet another optional form a horizontal pivot axis is located within an opening of the base.

According to another optional form, a heat sink is positioned at the back of the at least one solar panel. In another example, the heat sink includes a base section and plurality of fins produced from metal sheet by a rolling and then pressing process.

In another example embodiment, there is provided a system for electrical power generation, including: an array of solar panels supported by a plurality of floatation devices; a hydrogen generator to receive electrical power from the array of solar panels and use water, from the body of water, to produce hydrogen; and an electrical generator to receive the hydrogen and to produce electrical power. In one example, the hydrogen can be stored in one or more tanks for on demand use by the electrical generator.

### BRIEF DESCRIPTION OF FIGURES

Example embodiments should become apparent from the following description, which is given by way of example only, of at least one preferred but non-limiting embodiment, described in connection with the accompanying figures.

FIG. 1 illustrates a perspective view of an example floatation device.

FIG. 2 illustrates a front view of the example floatation device.

FIG. 3 illustrates a top view of the example floatation device.

FIG. 4 illustrates a right side view of the example floatation device.

FIG. 5 illustrates a bottom view of the example floatation device.

FIG. 6 illustrates a perspective view of an example array of floatation devices.

FIG. 7 illustrates a perspective view of an example array of floatation devices with attached solar panels,

FIG. 8 illustrates a front view of the array illustrated in FIG. 7.

FIG. 9 illustrates a rear view of the array illustrated in FIG. 7.

FIG. 10 illustrates atop view of the array illustrated in FIG. 7.

FIG. 11 illustrates a left side view of the array illustrated in FIG. 7.

FIG. 12 illustrates a right side view of the array illustrated in FIG. 7.

FIG. 13 illustrates a bottom view of the array illustrated in FIG. 7.

FIG. 14 illustrates a top view of an array of floatation devices with attached solar panels and an example rotation system.

FIG. 15 illustrates a perspective view of another example array of floatation devices having an alternate connection mechanism.

FIG. 16 illustrates a side view of the array illustrated in FIG. 15.

FIG. 17 illustrates a top view of the array illustrated in FIG. 15.

FIG. 18 illustrates a bottom view of the array illustrated in FIG. 15.

FIG. 19 illustrates a perspective view of another example array of floatation devices having below surface tanks and attached solar panels, the array being in a first pitch position.

FIG. 20 illustrates a side view of the array illustrated in FIG. 19.

FIG. 21 illustrates a top view of the array illustrated in FIG. 19.

FIG. 22 illustrates a bottom view of the array illustrated in FIG. 19.

FIG. 23 illustrates a side view of the array illustrated in FIG. 19 when the array is in a second pitch position.

FIG. 24A illustrates a perspective view of another example array of floatation devices having above surface tanks and attached solar panels, the array being in a first pitch position.

FIG. 24B illustrates a perspective view of the example array of floatation devices of FIG. 24A with the solar panels removed to more clearly illustrate the above surface tanks.

FIG. 25A illustrates a front view of the array illustrated in FIG. 24.

FIG. 25B illustrates a rear view of the array illustrated in FIG. 24.

FIG. 26 illustrates a side view of the array illustrated in FIG. 24.

FIG. 27 illustrates a bottom view of the array illustrated in FIG. 24.

FIG. 28 illustrates a perspective view of the array illustrated in FIG. 24 when the array is in a second pitch position.

FIG. 29 illustrates a front view of the array illustrated in FIG. 28 in the second pitch position.

FIG. 30 illustrates a side view of the array illustrated in FIG. 28 in the second pitch position.

FIG. 31 illustrates a perspective view of another example floatation device with attached solar panels, the solar panels being in a first pitch position.

FIG. 32 illustrates the floatation device of FIG. 31 in a second (fully upward or inclined) pitch position.

FIG. 33 illustrates the floatation device of FIG. 31 in a third (fully downward or flat) pitch position.

FIG. 34 illustrates a perspective view of another example floatation device with attached solar panels, the solar panels being in a first pitch position.

FIG. 35 illustrates the floatation device of FIG. 34 in a second pitch position.

FIG. 36 illustrates a perspective view of another example floatation device with a fixed pitch position of attached solar panels.

FIG. 37 illustrates a schematic of an example process for producing a heat sink.

FIG. 38 illustrates an example system for power generation.

### PREFERRED EMBODIMENTS

The following modes, given by way of example only, are described in order to provide a more precise understanding of the subject matter of a preferred embodiment or embodiments.

In the figures, incorporated to illustrate features of an example embodiment, like reference numerals are used to identify like parts throughout the figures.

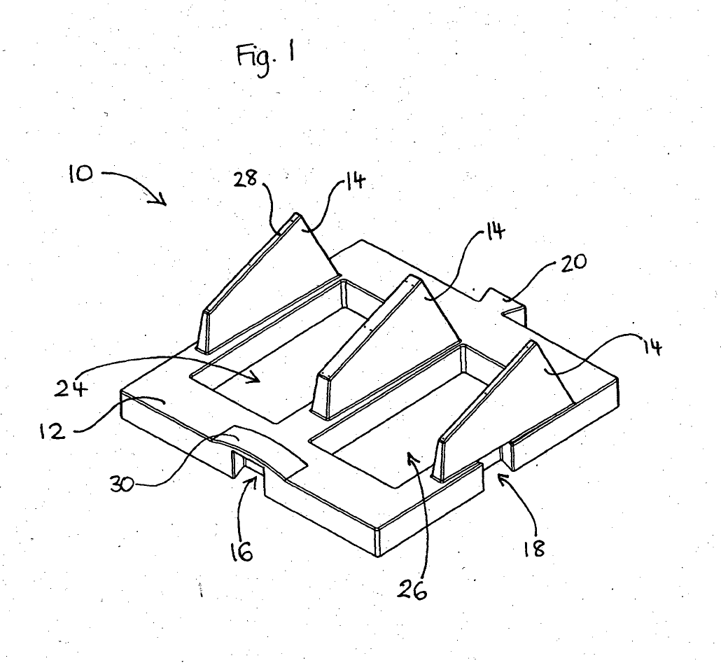

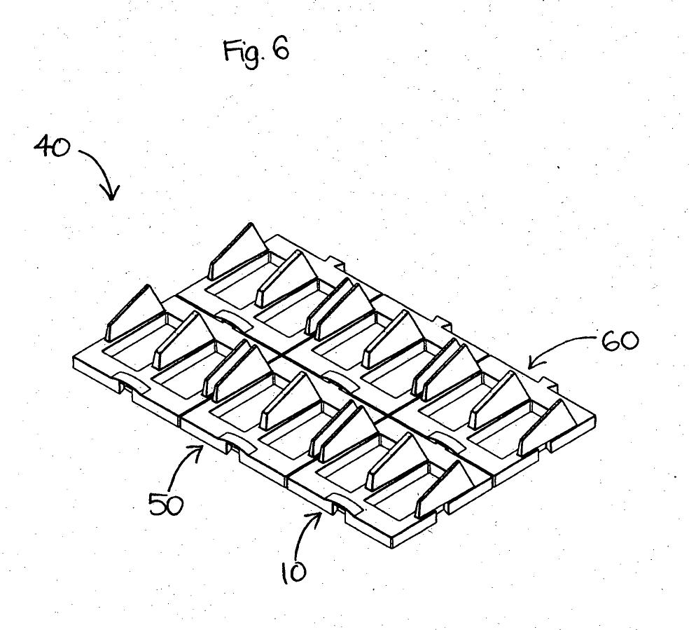

Referring to FIG. 1 there is illustrated a floatation device 10 for supporting at least one photovoltaic solar panel (not illustrated) above a body of water. Floatation device 10 includes a base 12 able to float on the body of water. The base may be partially or fully submerged so long as supported photovoltaic solar panels are above the surface of the body of water. Also provided is at least one support 14 used to position at least one photovoltaic solar panel at an angle (i.e. pitch angle) to base 12. At least one support 14 is used to hold or mount at least one photovoltaic solar panel at a desired pitch angle relative to the base, where the angle can be either fixed or variable depending on the type of support 14 used. At least one coupling member 16, 18, 20, 22 is provided to couple floatation device 10 to an adjacent floatation device (see FIG. 6).

Preferably, though not necessarily, base 12 includes at least one opening 24, 26 passing through base 12. A solar panel, when positioned on support 14, is hence positioned above and away from the at least one opening 24, 26.

Support 14 can be provided with a support surface 28. The support surface 28 can be integrated with support 14 or provided as an attached separate component. Support surface 28 is a surface that contacts a mounting back-plate or bracket of a photovoltaic solar panel, which can be any number of commercially available solar panels. Support surface 28 can be provided with, for example, holes or other attachment mechanisms to allow one or more solar panels to be positioned and held.

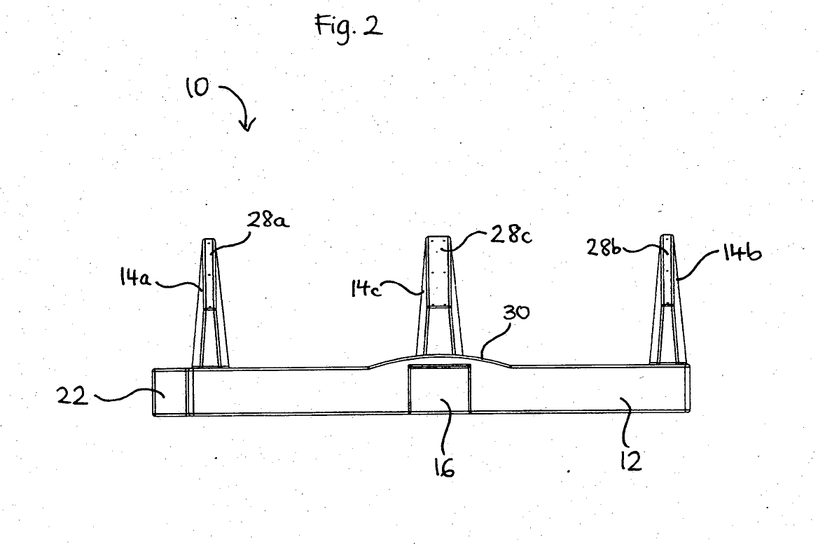

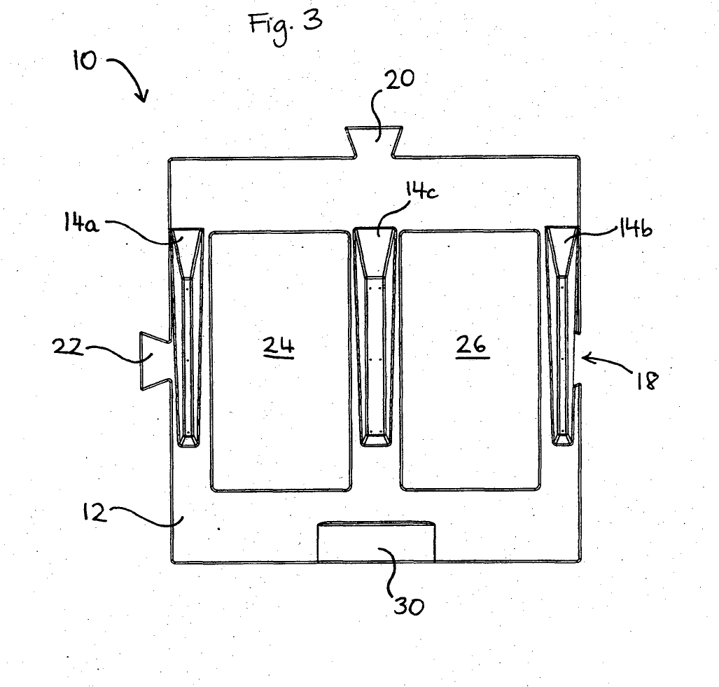

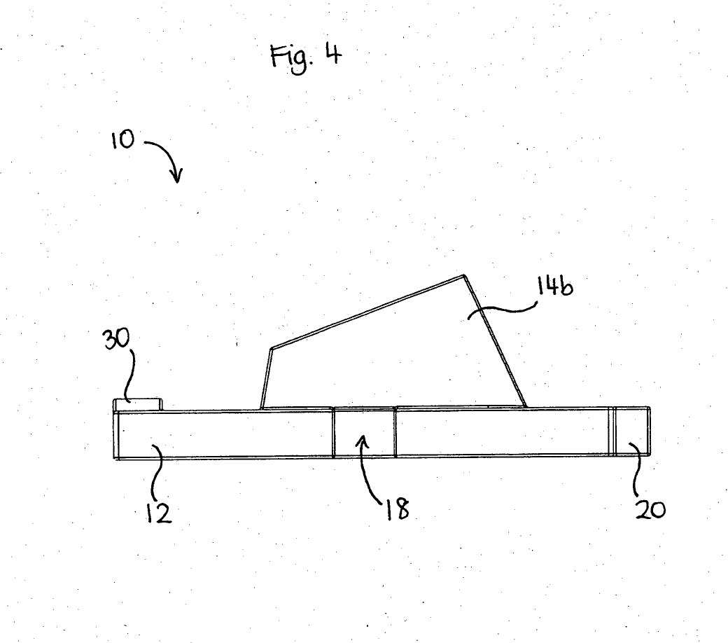

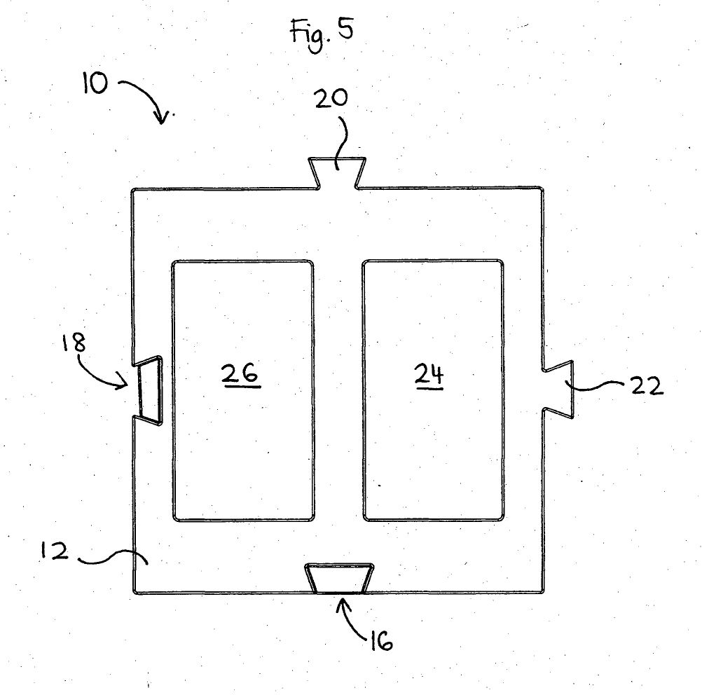

Reference is also made to FIGS. 2 to 5 which illustrate different views of floatation device 10. Preferably, though not necessarily, base 12 includes first opening 24 and second opening 26. The presence of an opening is optional, and furthermore the number and geometry of openings is also optionally variable. For example, 1, 2, 3, 4, etc. openings could be provided in various geometries (e.g. rectangular, square, circular, etc.) and/or positions about base 12. Openings 24, 26 assist to dissipate wave energy on the surface of the body of water. Openings 24, 26 can also assist to retain cooler air and cool an adjacent solar panel, which provides efficiency gains in silicon based solar panels.

The at least one support 14 is preferably a protrusion, extension, arm, strut or the like, extending from the base 12 and having a support surface 28 that is made to mount a solar panel at an angle in relation to the surface of the base 12. A wide variety of shapes or configurations of support can be used. The support need not be solid as illustrated but could be a framework, struts and/or brackets, to support a solar panel. A solar panel is fixed to the support surface 28, for example by using one or more threaded screws to hold a bracket of the solar panel to the support.

In an example form, as illustrated, there are three supports provided, being a first end support 14a positioned near an edge of base 12, a second end support 14b positioned near an opposite edge of base 12, and a middle support 14c positioned between first opening 24 and second opening 26. First end support 14a can be provided with associated support surface 28a, second end support 14b can be provided with associated support surface 28b, and middle support 14c can be provided with associated support surface 28c.

Supports 14a, 14b and 14c are illustrated as rigid components and thus the pitch angle of the support surfaces 14a, 14b and 14c, that hold solar panels, is fixed. In an alternate embodiment, supports can be provided that allow the support surface to be angled or rotated to change the pitch angle of the support surface relative to base 12. For example, an end of a support may be pivoted at, near, or within the opening of, base 12, or at or near the support surface; with the other end of the support free to move in a generally upward or downward motion, thereby varying the pitch angle of the support surface relative to base 12. A variety of locking mechanisms can be provided to fix the pitch angle of the support surface relative to base 12 when a desired pitch angle is obtained. A wide variety of arrangements of providing a variable pitch angle using a support can be implemented. This includes mechanical arrangements, hydraulic arrangements, and/or electro-mechanical arrangements where an electronically controlled mechanism can provide for automated changes in pitch angle.

In another embodiment, it might be considered that two pitch angles are sufficient, for example corresponding to summer and winter positions, or spring and autumn positions, of the sun. Fixed supports may be used providing a first pitch angle and a second different pitch angle could be obtained by attaching or inserting an appropriately shaped/angled block or wedge to support surface 28. This could be used to provide a new support surface at a different pitch angle.

In yet another embodiment the angle of a surface of base 12 itself relative to the surface of the body of water (i.e. base angle) can be varied by increasing or decreasing the height of one end of floatation device 10 with respect to the surface of the body of water. A change in base angle will provide a corresponding change in pitch angle. For example, a ballast tank or container can be positioned within, near, above and/or underneath one or both ends of base 12 that is operable to adjust the base angle. For, example, air or liquid (for example water) can be input or released from the ballast tank or container to affect the buoyancy of an end of base 12 to thereby adjust the base angle, resulting in a corresponding change in pitch angle of a solar panel supported by support surface 28.

In one example embodiment, the ballast tank or container could be a “weight” tank. The weight tank can be positioned either forward or aft of the solar panels. Preferably, though not necessarily, the weight tank is an above surface, or at least partially above surface, tank which could be filled, and emptied, using liquid (preferably water). By adjusting the quantity of liquid the pitch of the floatation device can be adjusted.

In another example embodiment, the ballast tank or container could be an “under surface” tank with a downward facing opening (i.e. utilising an upside down bucket principle). In the neutral position the under surface tank would be full of water. By pumping air (typically low pressure, high volume air) into the top region of the tank, the contained water can be forced out through the downward facing opening (i.e. bottom opening), thus providing additional floatation and adjustment of the pitch of the floatation device.

The at least one coupling member used to couple floatation device 10 to an adjacent floatation device 50 or 60 (see FIG. 6) can be a wide variety of mechanical coupling arrangements. Any suitable mechanical coupling that reliably holds floatation device 10 in position relative to adjacent floatation devices 50 or 60 can be used. This could include a variety of interlocking projection and recess arrangements, that could be provided, for example, in a clip-together or sliding locking arrangement. A wide variety of different types of connecting arms, linkage members, brackets, links, rods, ties, cables, etc. could be utilised as coupling members. Spring-based, or resilient coupling members that allow some relative movement of floatation devices also could be used. For clarity, the coupling between floatation devices can be a direct join or coupling of members or can be a flexible, moveable or sprung coupling arrangement. As would be appreciated a large variety of mechanical couplings or joints could be readily applied to couple floatation devices.

In the preferred form as illustrated, at least one coupling member is provided as at least one recess 16, 18 within base 12, that is extending into the extent of base 12. A further at least one coupling member is provided as a projection 20, 22 as part of base 12. Recess 16, 18 is able to couple or join with a corresponding projection of an adjacent floatation device 50, 60 to form a joint. Projection 20, 22 is able to couple with a corresponding recess of adjacent floatation device 50, 60 to likewise form a joint. Preferably, a coupling member is a recess, such as a mortice. Also preferably, a coupling member is a projection, such as a tenon.

Optionally, recess 16 can be covered by additional material providing hump 30 so that sufficient material is provided about recess 16 to provide suitable or improved integrity or rigidity in the vicinity of recess 16. Recess 18 is in the vicinity of support 14 thus avoiding any requirement for similar additional material to be placed above recess 18.

Referring to FIG. 6 there is illustrated an array 40 of floatation devices formed by coupling or joining a plurality or floatation devices together. For example, floatation device 10 is coupled or joined to adjacent floatation devices 50 and 60. In this manner an array of any desired geometry can be constructed using floatation device 10 as a base unit.

The floatation device 10, and parts thereof, can be integrally formed or can be assembled as components. Preferably, base 12 is integrally formed as a section, that is buoyant, including at least one opening. Preferably, floatation device 10 is made of plastic. Floatation device 10 can be formed as a hollow body or shell to improve buoyancy, however, floatation device 10 could be a solid body. Also, a hollow body or shell can be filled with a buoyant material to increase overall buoyancy of floatation device 10, such as an expanded polymer, for example expanded polystyrene (EPS) or expanded polyurethane (EPU). Preferably, floatation device 10 can be manufactured from a low to medium density polyethylene. However, it should be appreciated that a wide variety of other materials or composites, including synthetic or semi-synthetic materials, can be used to produce floatation device 10.

A wide variety of dimensions of floatation device 10 can be manufactured, typically depending on an associated size of solar panel that floatation device 10 is to be used with. In a non-limiting embodiment, provided by way of illustrative example, the dimensions of the base may be 2100 mm×2050 mm×200 mm. The top front corner of support 14 may extend 250 mm above the surface of base 12 and support surface 28 of support 14 may be set at a pitch angle of 20° relative to the top surface of base 12.

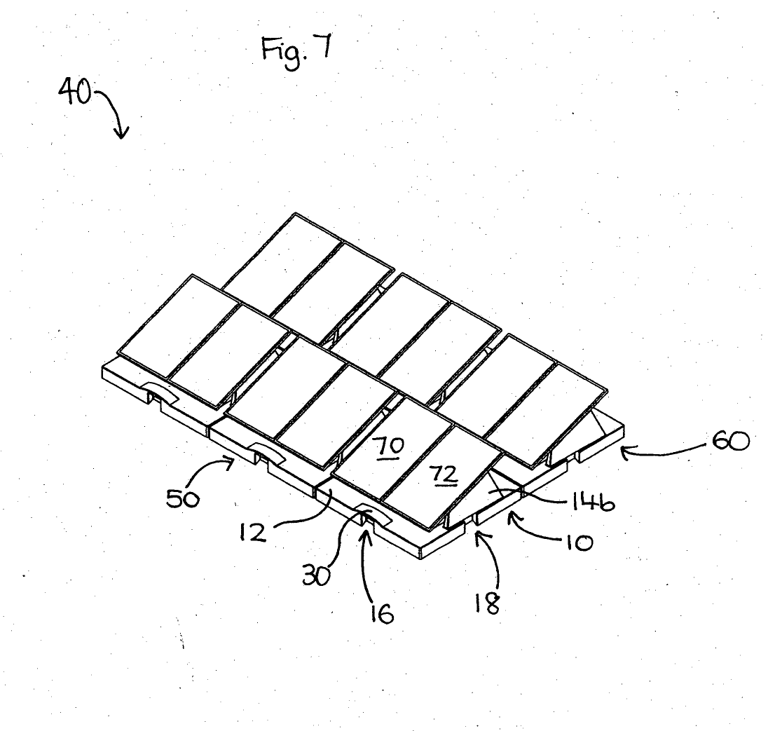

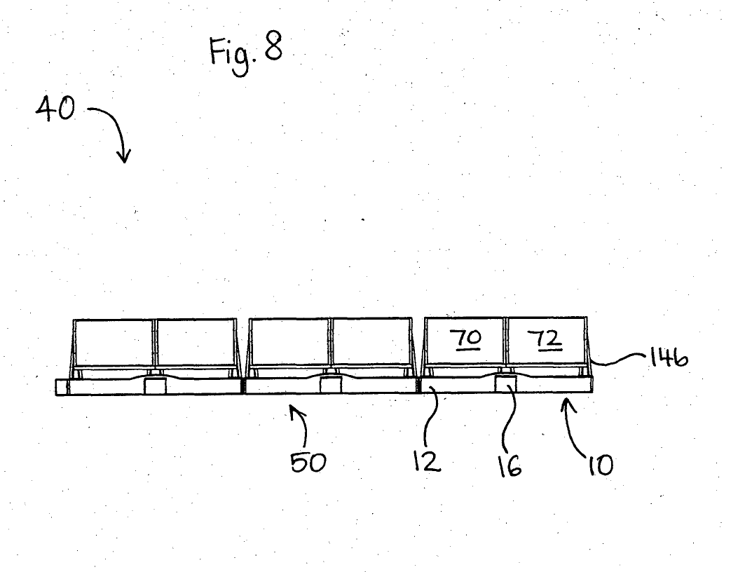

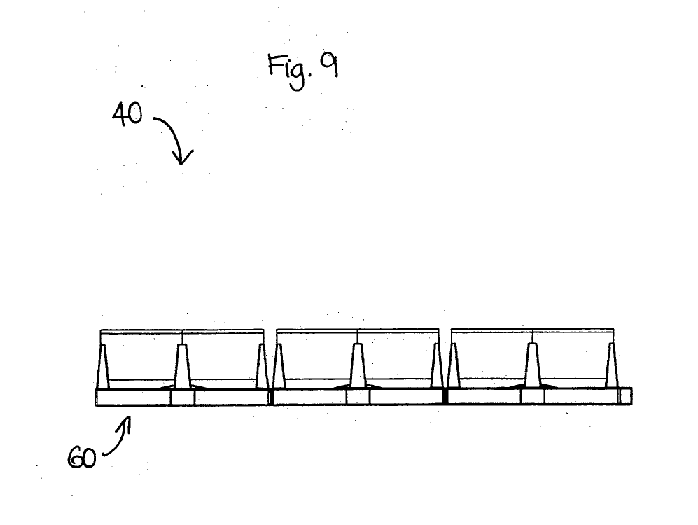

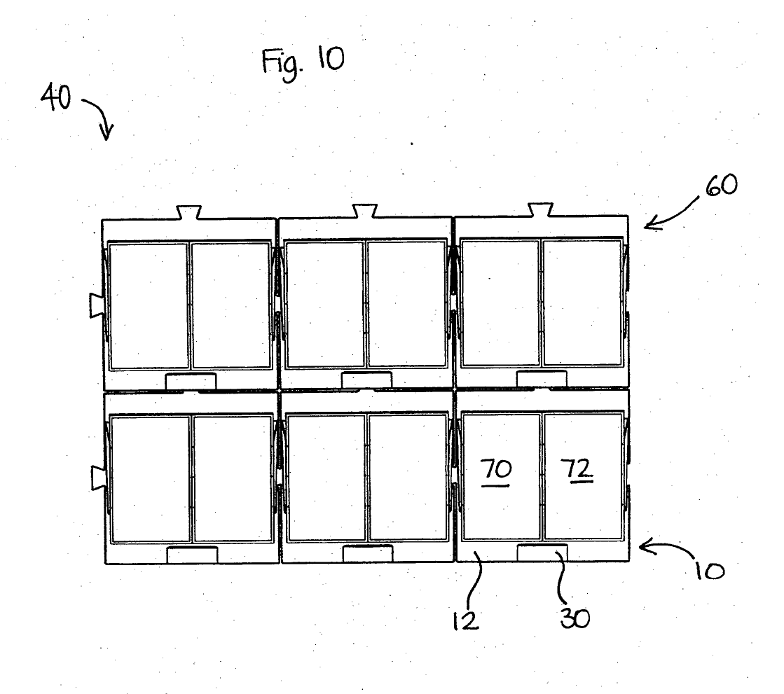

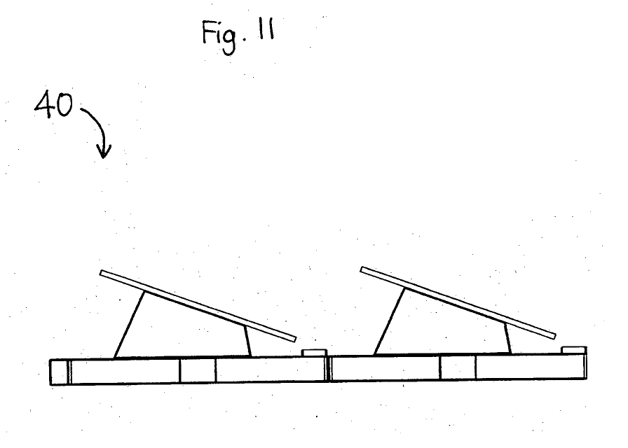

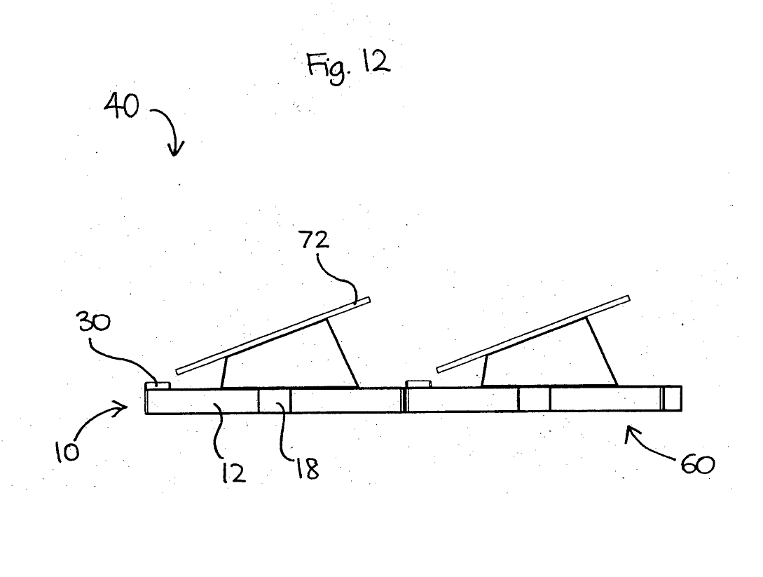

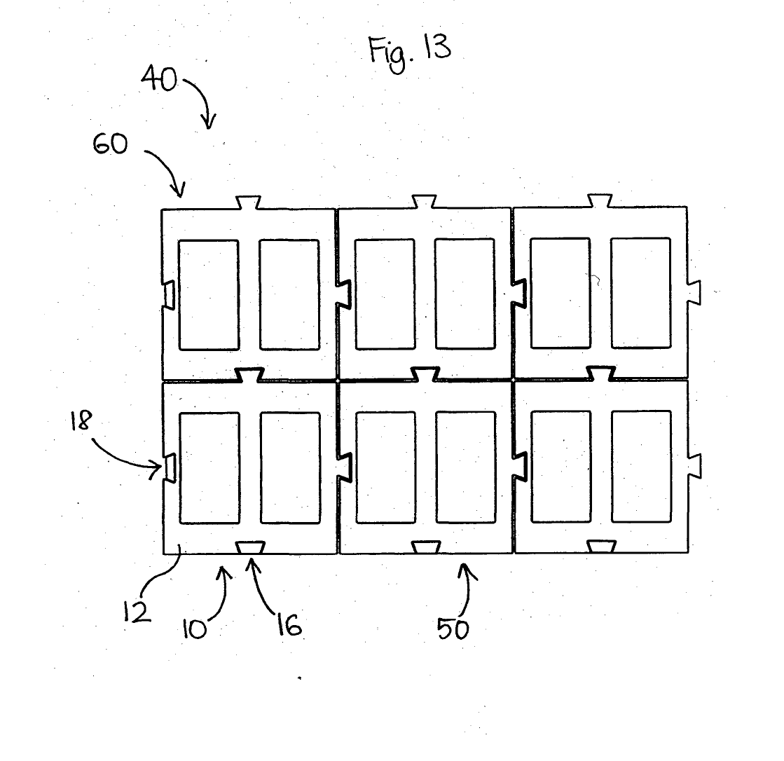

Referring to FIGS. 7-13 there is illustrated array 40 of floatation devices with photovoltaic solar panels attached. Floatation device 10 has first solar panel 70 and second solar panel 72 attached. First solar panel 70 is attached to and supported by supports 14a, 14c and second solar panel 72 is attached to and supported by supports 14b, 14c. Passages or walkways are provided between joined floatation devices to enable access for cleaning or maintenance.

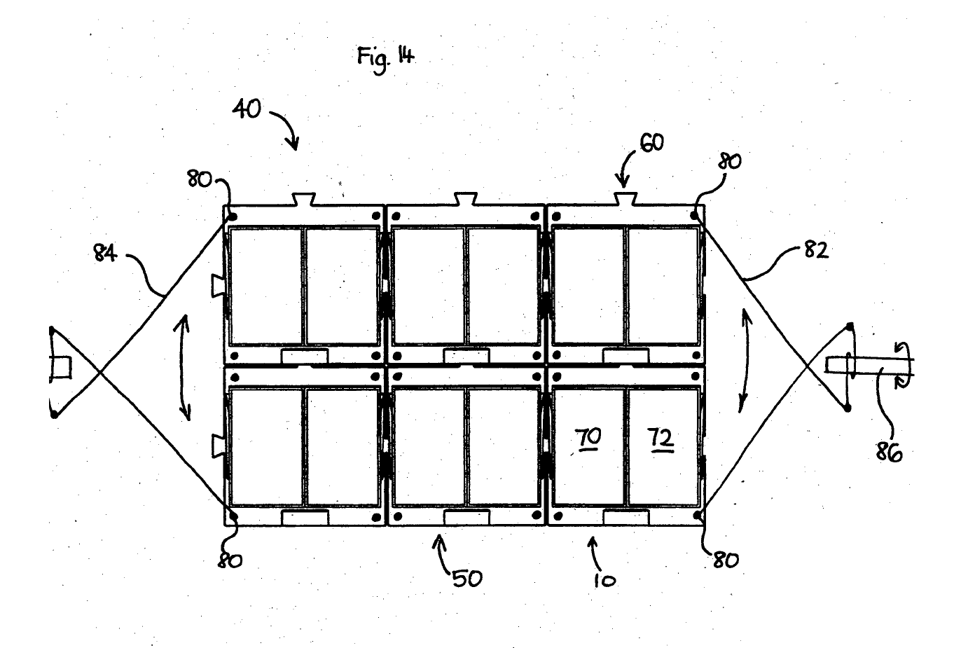

Referring to FIG. 14 there is illustrated a further optional embodiment showing array 40 of floatation devices with each floatation device provided with at least one anchor point 80. Anchor points 80 could be, for example, a protrusion, projection, ring, etc. to which a cable, wire, rope, line, etc. can be attached. Alternatively, anchor points 80 could be a form of recess. Cable 82 is attached to an anchor point 80 and can thus be used to rotate array 40 on the surface of a body of water. By pulling or otherwise applying a force to cable 82 this provides a simple means to rotate array 40 about a normal direction to the surface of the body of water. To assist in reproducible or stable rotation, an opposing corner could be, if possible, fixed, for example by being fixed to the ground beneath the body of water or by being fixed using cables to points at the edge of the body of water.

A variety of mechanisms to achieve rotation of array 40 can be utilised, including mechanical arrangements, hydraulic arrangements, and/or electro-mechanical arrangements where an electronically controlled mechanism can provide for automated changes in rotation angle.

In an example embodiment for rotating array 40, cable 82 may be wound about, or otherwise attached to or associated with, a rotatable shaft 86. Likewise, cable 84 may be wound about, or otherwise attached to or associated with, rotatable shaft 88. By rotating shafts 86, 88, independently or in combination, a force is applied to cables 82, 84 resulting in rotation of array 40 of floatation devices. Rotatable shafts 86, 88 could be simply rotated mechanically, for example by a human operator, or by using an electronic control unit. If an electronic control unit is used hydraulics could assist or be used to rotate shafts 86, 88 as required. For example, a simple timing device could be used in the electronic control unit to rotate shafts 86, 88 at a determined rate to approximately match rotation of array 40 to track the movement of the sun across the sky. Alternatively, a more complex electronic control unit could include a photo-sensor(s) to track the movement of the sun across the sky during the day and produce an output signal to control rotation of shafts 86, 88 to correspondingly align the rotation angle of array 40 to gain optimal exposure to solar radiation as the sun moves across the sky.

The following examples provide further discussion of various embodiments. The examples are intended to be merely illustrative and not limiting to the scope of the present invention.

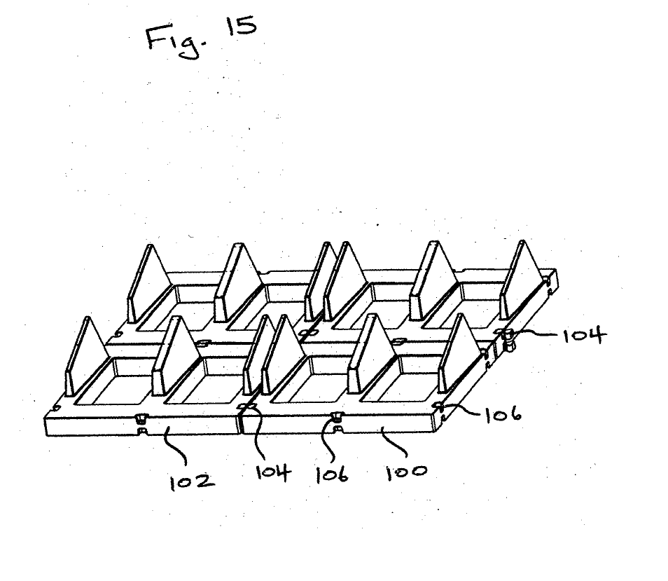

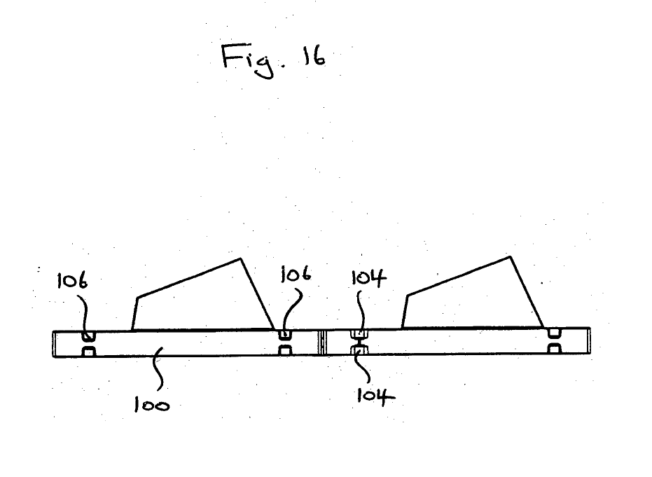

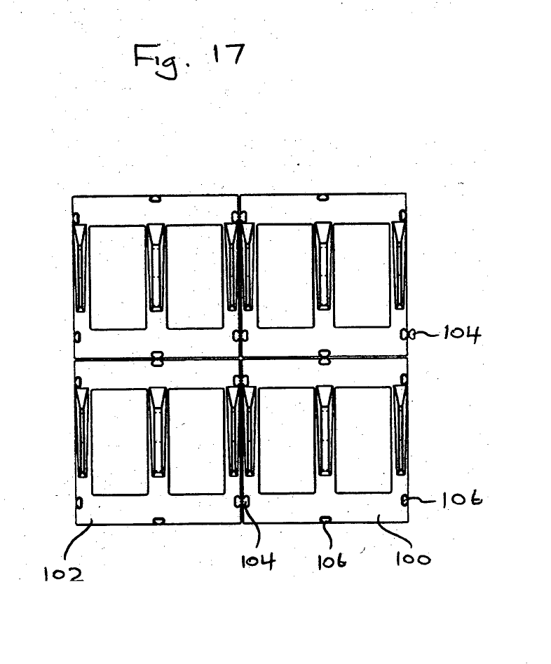

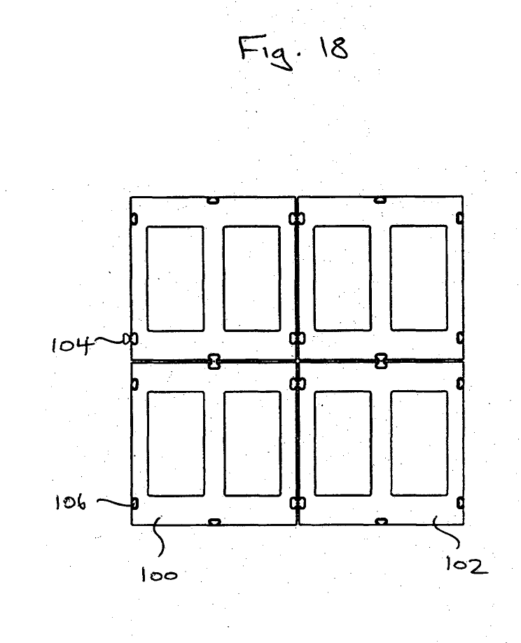

Referring to FIGS. 15 to 18 there is illustrated an alternate coupling member used to couple floatation device 100 to an adjacent floatation device 102. The illustrated alternate coupling members are a type of removable linkage member, for example dog bone members 104 that can be positioned in recesses 106. Dog bone members 104 are preferably flexible (e.g. made of rubber) and are removably positioned and held in recesses 106 so as to join adjacent floatation devices. Dog bone members 104 and recesses 106 can be provided on both upper and/or lower surfaces of a base section of a floatation device. This allows relative movement of adjacent floatation devices to accommodate for wave action.

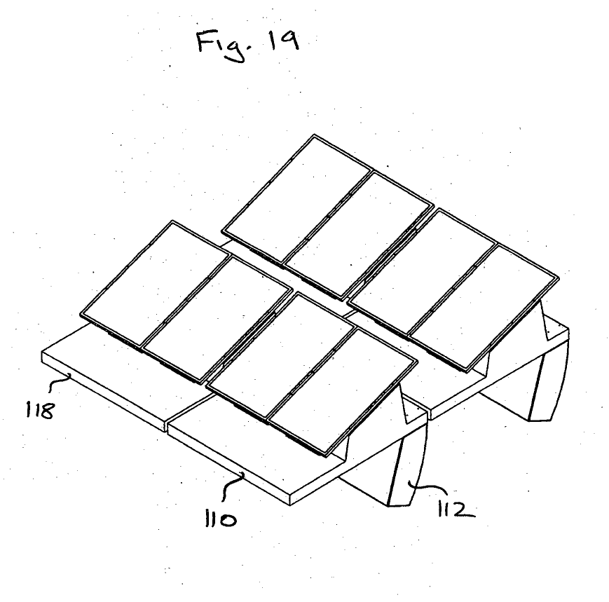

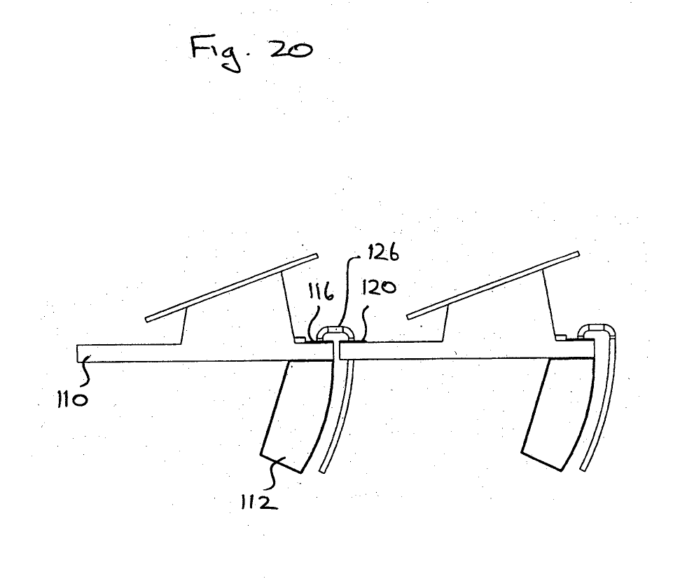

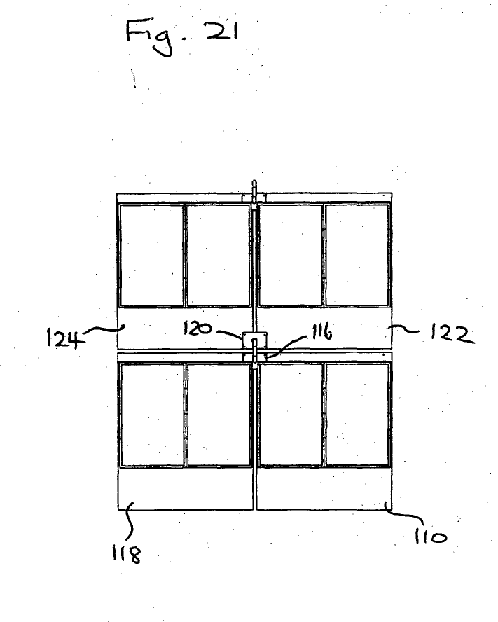

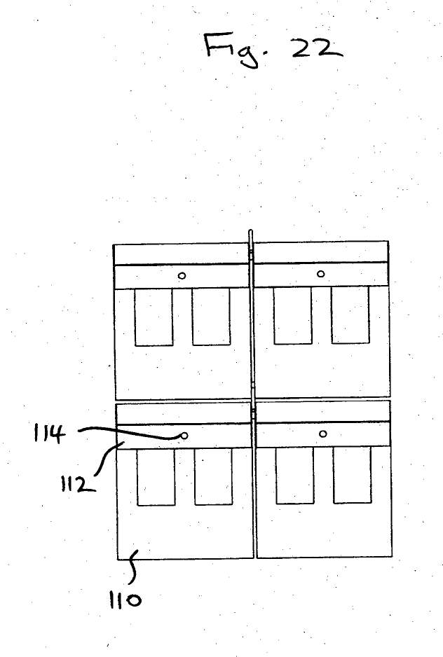

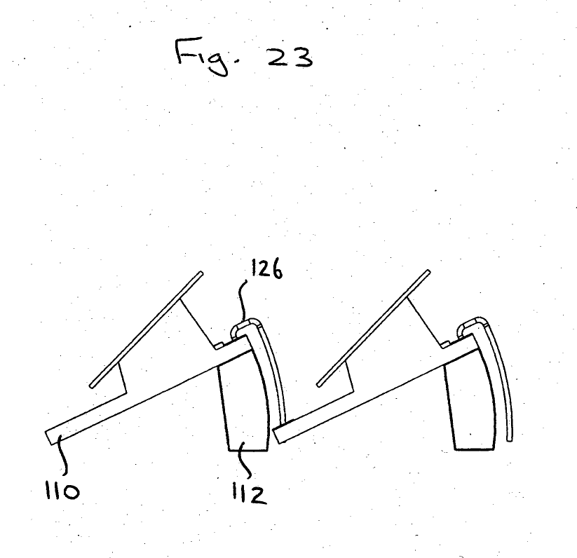

Referring to FIGS. 19 to 23 there is illustrated an alternate mechanism for controlling the base angle and thus the pitch angle of the solar panels. Floatation device 110 has an attached “below surface” tank 112. By pumping air into a top region of tank 112, for example via an orifice, hole, valve, etc., this causes water to be pushed out of a lower orifice 114, thus creating buoyancy. This results in floatation device 110 pitching forward from a first pitch position (e.g. Summer (midday) position shown in FIGS. 19 to 22) to a second pitch position (e.g. Winter (morning / afternoon) position shown in FIG. 23).

In the alternate embodiment shown in FIGS. 19 to 23, there is also shown another alternate connection mechanism to join adjacent floatation devices. Plate 116 holds together an adjacent pair of floatation devices, i.e. floatation device 110 and floatation device 118. Plate 120 holds together floatation device 122 and floatation device 124. Plate 116 has an attached arm or pipe arrangement 126 that passes through a hole or orifice in plate 120, thus flexibly holding floatation devices 110, 118 in position relative to floatation devices 122, 124. This arrangement allows for a change in base angle (and thus pitch angle) whilst still holding floatation devices in an adjacent position. In a particular example, stainless steel plate and pipe can be used.

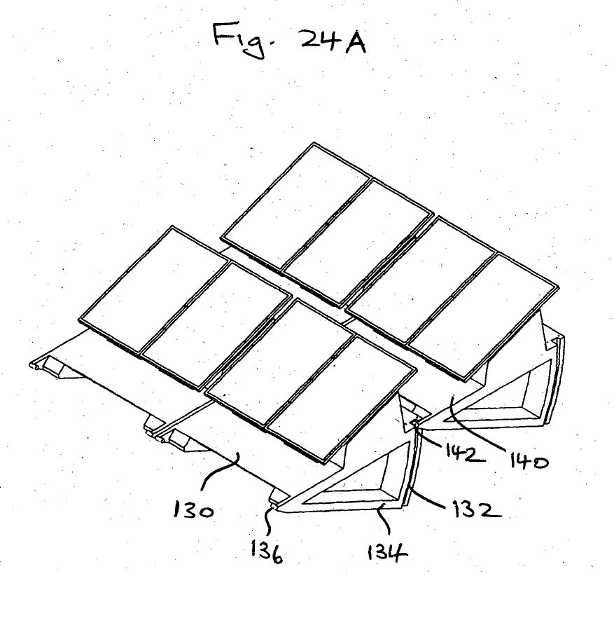

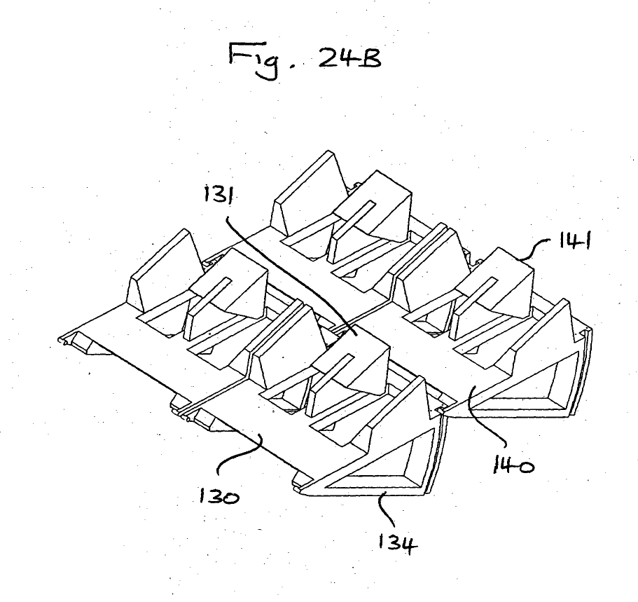

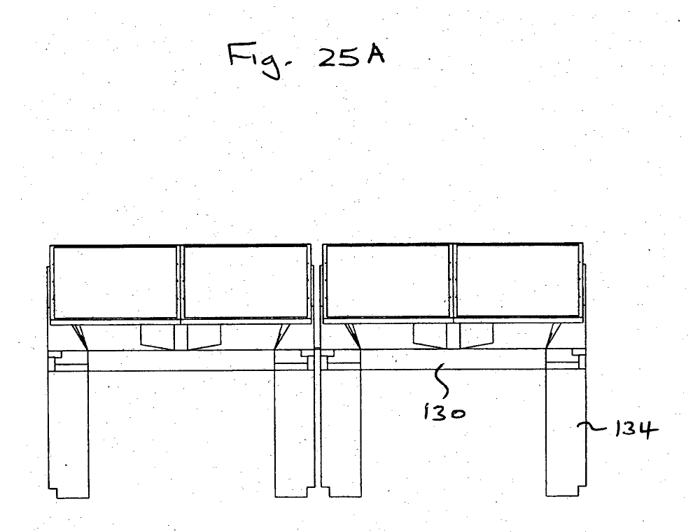

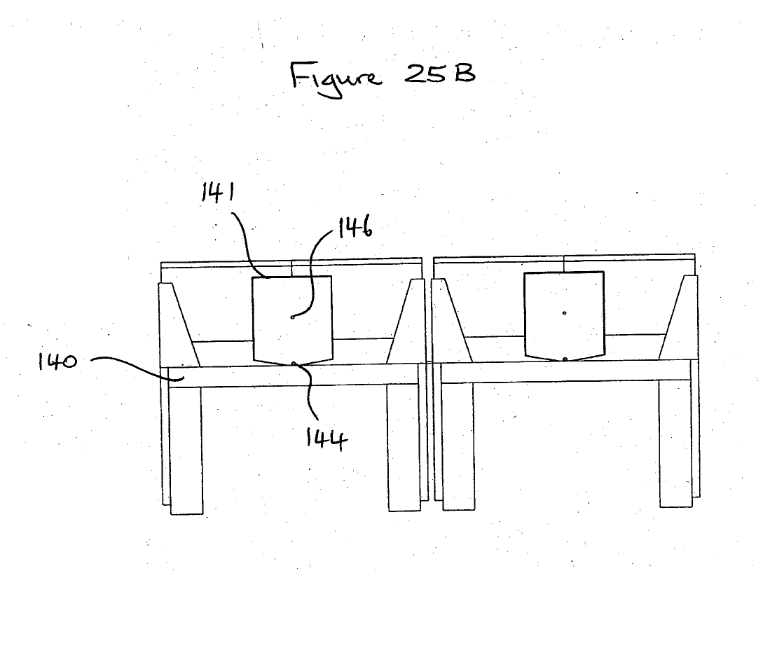

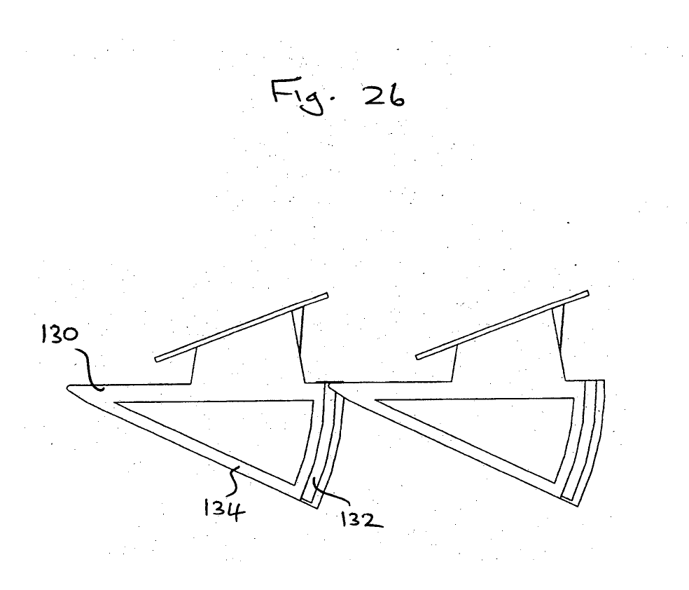

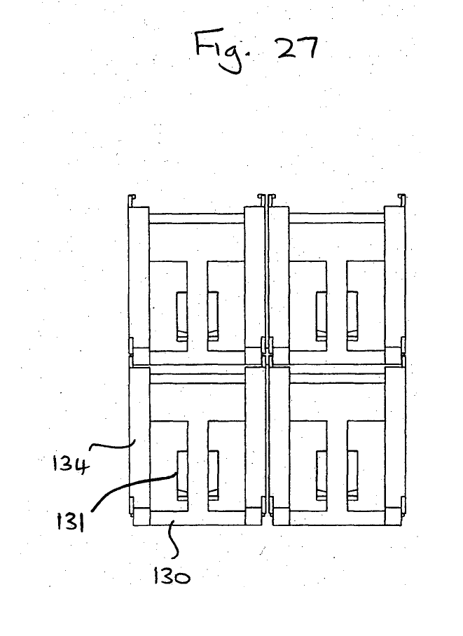

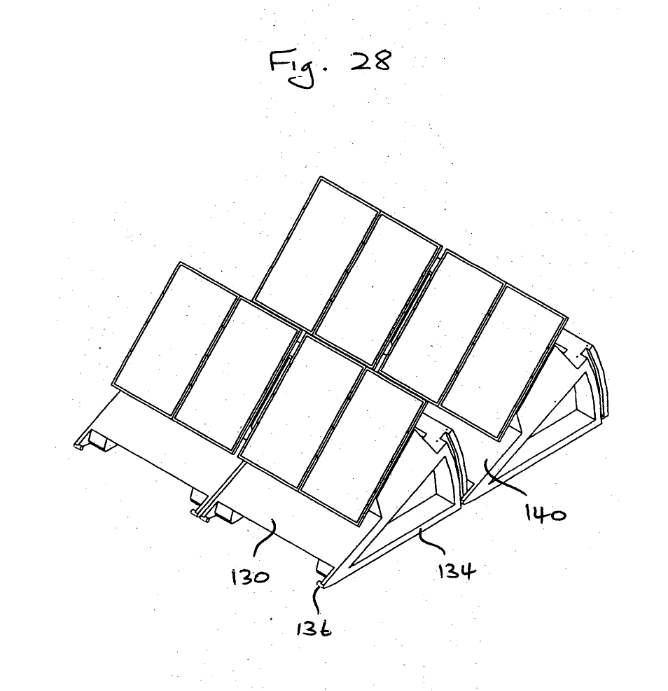

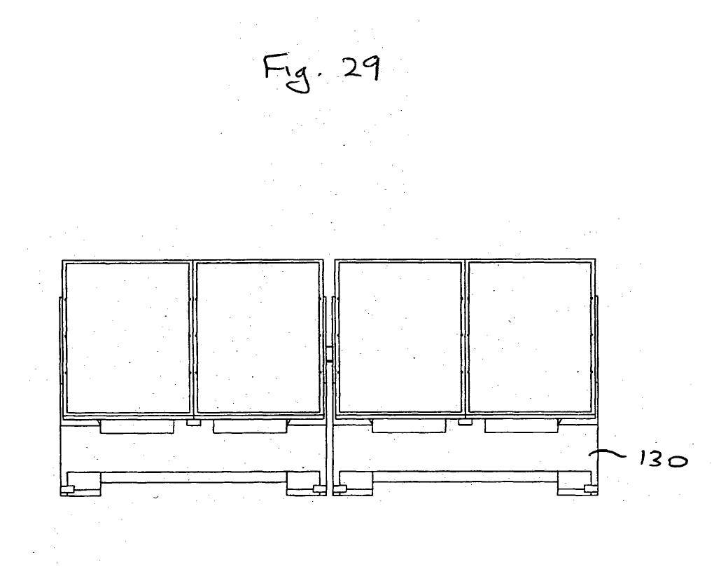

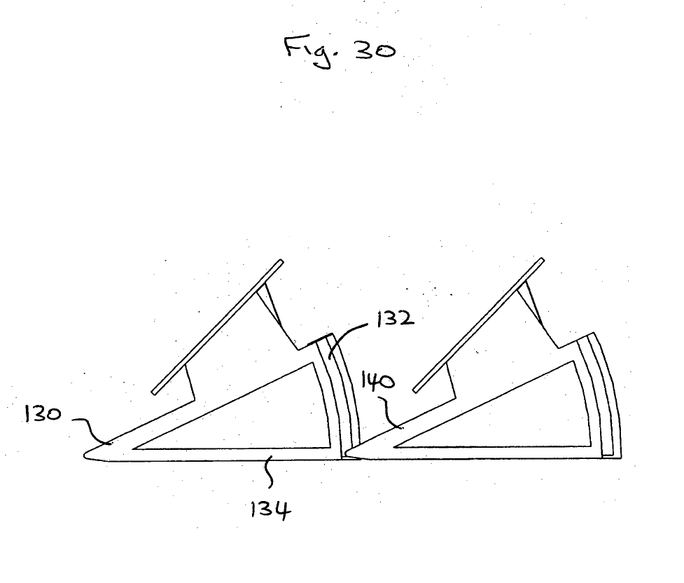

Referring to FIGS. 24 to 30 there is illustrated another alternate mechanism for controlling the pitch angle of the solar panels. Floatation device 130 includes an “above surface” tank 131, or other form of container or weighting mechanism that can be either internal or external. In another example, it is possible to use the above surface tank 131 in conjunction with the below surface tank 112. Filling the above surface tank 131 with water causes the floatation device 130 to pitch backward from a first pitch position (e.g. Winter (morning/afternoon) position shown in FIGS. 28 to 30) to a second pitch position (e.g. Summer (midday) position shown in FIGS. 24 to 27). As the water is emptied, or weight otherwise removed, the floatation device 130 returns to the first pitch position (e.g. Winter (morning/afternoon) position). Tanks of adjacent floatation devices are preferably connected in parallel, thus enabling the pitch angle of all connected floatation devices to be adjusted simultaneously, and can be formed as an internal part or cavity of a floatation device. Floatation device 140, provided with above surface tank 141, includes port 144 for filling and/or emptying of water at or near the base of tank 141. Hole 146 is provided as a breather or venting hole.

Floatation device 130 includes a recess or groove 132, that may be arcuate as illustrated, in support structure 134. Finger or other protrusion 136 is adapted to slidingly engage with an associated arcuate recess or groove of another floatation device. Floatation device 140, provided with above surface tank 141, includes a corresponding finger 142 that slidingly engages with arcuate recess or groove 132. This arrangement holds floatation devices 130, 140 in position whilst allowing a change in base angle of floatation devices 130, 140. Preferably, a pair of support structures, arcuate recesses and fingers are provided as part of a floatation device, as illustrated.

In a non-limiting example, liquid or air can also be allowed enter or exit an interior hollow region of the base, if provided, which is connected, i.e. can exchange liquids/air, with an interior region of the ballast tank or container.

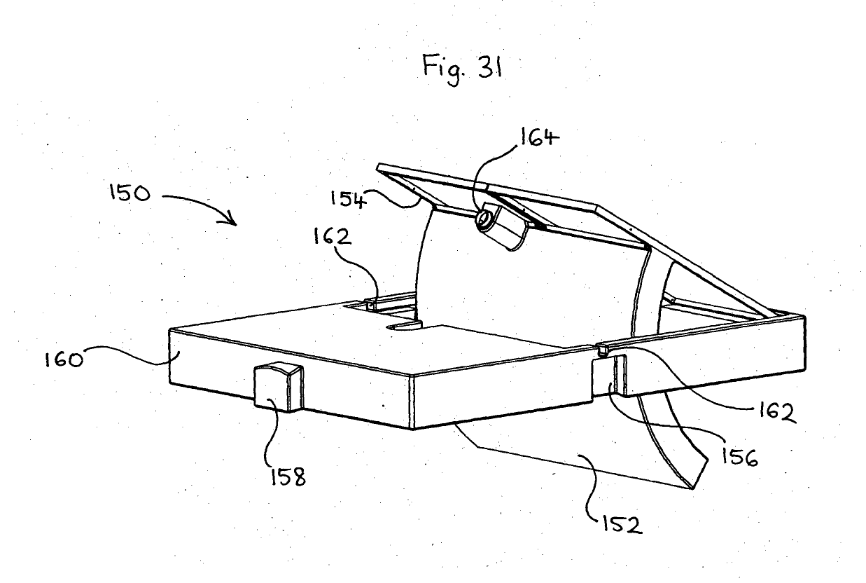

Referring to FIGS. 31 to 33, there is illustrated another alternate mechanism for controlling the pitch angle of one or more solar panels. Floatation device 150 includes tank 152 or other type of container. Filling the tank 152 with water or air (or otherwise removing water or air) causes tank 152, and thus also attached support frame 154, to raise or lower, thereby altering the pitch angle of attached solar panel(s) 156 relative to base 160. A variety of shapes or configurations of tank 152, and frame 154, are possible. Also, it is possible to use tank 152 (controlling pitch angle) together with either or both of tanks 112, 131 (controlling base angle).

In one example for attachment to adjacent devices, floatation device 150 can include one or more mortices 156, and one or more tenons or projections 158 for interconnecting adjacent floatation devices. Mortices and tenons, or other connection mechanisms, can be provided at a variety of locations about the sides of base 160 of floatation device 150, for example as hereinbefore described. Optionally, base 160 can provide one or more recesses into which a further joining or locking member can be inserted to assist in holding together adjacent floatation devices as an array of floatation devices.

Thus, there is provided a floatation device that offers a variable pitch angle for one or more solar panels attached to and supported by the floatation device. FIG. 31 illustrates floatation device 150 in an intermediate pitch angle or position. Tank 152 is part of or attached to frame 154, that is able to pivot about a lower end, for supporting one or more solar panels. In one form, frame 154 may be part of the solar panels themselves, that is attached to a top surface of tank 152. The solar panels themselves could be, in some forms, considered as a structural element that pivots about a lower horizontal axis, which may be within the opening of base 160. Tank 152 is movable within and extends through the opening of base 160. A pivoting action of solar panels can be provided using a variety of mechanisms, such as bolts, rods, hinges or the like.

Air can be pumped into tank 152, for example high volume, low pressure air, using hole 164, which can act as an air inlet/outlet. When air is forced into tank 152 this forces water to escape via a hole (not illustrated) in the base of tank 152, thereby causing increased buoyancy of tank 152. Changes in buoyancy of tank 152 can be utilised to vary the pitch angle of the one or more solar panels attached in fixed relation to tank 152. Slots/protrusions can be provided as part of an exterior surface of tank 152 and/or on a surface of opening of base 160 that act as guides for tank 152 during movement of tank 152 within the opening.

Surface slots or channels 162 near a top surface of base 160 can be used to accommodate one or more electrical cables, that interconnect between solar panels on adjacent floatation devices, when one or more solar panels are in a fully downward (i.e. flat or horizontal) position. Photovoltaic solar panels could be assembled prior to transportation, and floatation devices could be assembled on-site. Although a variety of different transport/assembly scenarios are possible.

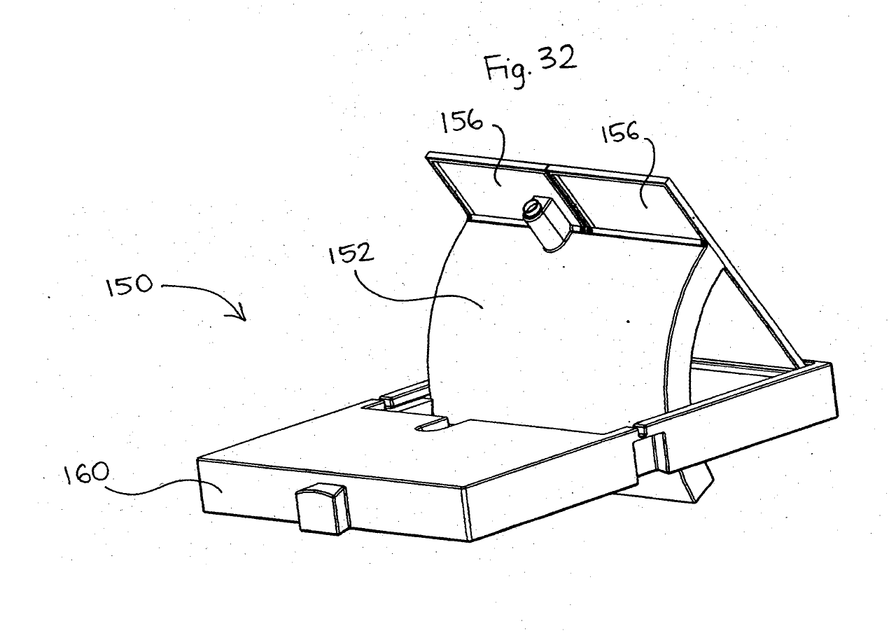

Referring to FIG. 32, floatation device 150 is illustrated with one or more solar panels 156 in a second pitch position, being in a fully upright or inclined position. The extent to which tank 152 can traverse in an upward direction can be mechanically and/or electronic control feedback limited, for example so that at a fully upright position there remains a significant amount of water in a bottom region of tank 152. This remaining volume of water can assist in preventing wind from blowing over floatation device 150.

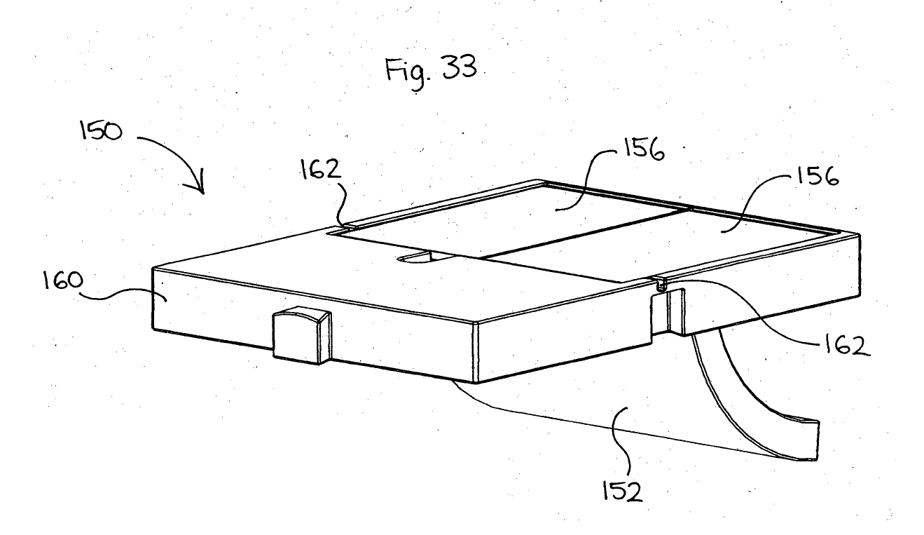

Referring to FIG. 33, floatation device 150 is illustrated in a third pitch position, being a fully downward or flat position. By removing air via hole 164 of tank 152, or a projection extending from tank 152, or otherwise forcing water into tank 152, the buoyancy of tank 152 decreases and the pitch angle of one or more solar panels 156 lowers towards a horizontal position as illustrated.

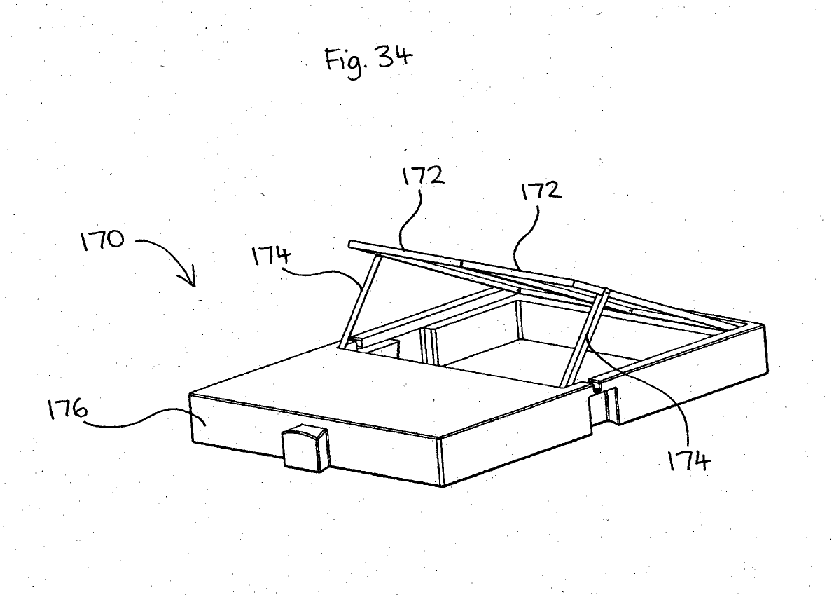

Referring to FIG. 34, there is illustrated another alternate mechanism for controlling or setting the pitch angle of one or more solar panels. Floatation device 170 provides fixed angles for different pitch angles of one or more solar panels 172. Floatation device 170 provides a thinner device that can significantly reduce transportation costs. One or more solar panels could be attached with all hardware prior to transportation, and yet assembled floatation devices still could be stacked for transportation.

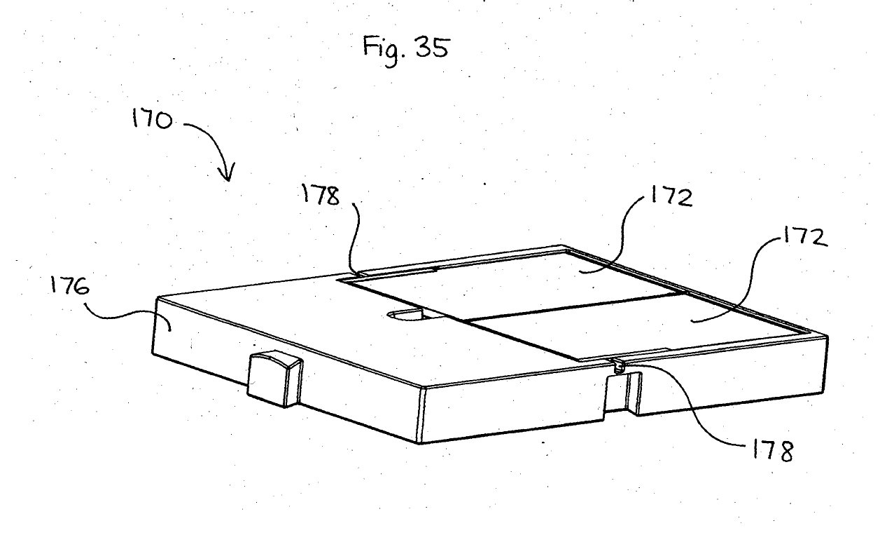

Struts 174 are provided to position one or more solar panels 172 at a first pitch position. Referring to FIG. 35, struts can be removed, repositioned or collapsed so as to allow one or more solar panels 172 to be moved to a second pitch position, being substantially flat or horizontal. Struts 174 could be fixed or removable, or provided as different fixed lengths depending on a desired inclined pitch angle. Alternatively, fixed length struts could be provided that are releasably attached to or slotted in variable locations at one end, such as within the opening of the base, so that different fixed, pitch angles are achieved. Still furthermore, struts 174 could be telescopic or extendable and able to be expanded/retracted so as to provide variable pitch angles. Slots 178, or channels, can be provided to allow electrical cables to interconnect between solar panels on adjacent floatation devices.

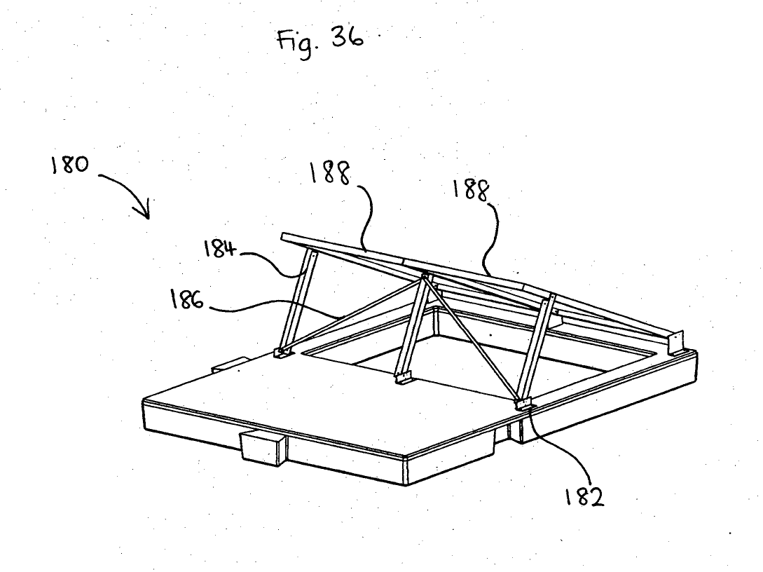

Referring to FIG. 36, there is illustrated another alternate form of floatation device 180, again providing a simplified and relatively thin device that can assist in transportation and/or reducing manufacturing costs. In this example embodiment, no attachment hardware is provided at a moulding production stage for reduced cost and simplicity of production. Various brackets 182, struts 184 and straps 186 can be provided, in a variety of configurations, to support one or more solar panels 188 at a fixed pitch angle. In one form, brackets 182, struts 184 and straps 186 could be made of aluminium, although a variety of other materials could be utilised.

In the various floatation devices illustrated or discussed, integral joining elements can be utilised. Preferably, though not necessarily, a relatively large aperture or opening in a base section is provided to allow advantageous cooling of one or more solar panels by being placed above a body of shaded water.

Preferably, though not necessarily, an expanded polymer, for example expanded polystyrene (EPS) or expanded polyurethane (EPU), is used inside the base section, which in this example is initially hollow or provided as a skin, and/or other hollow sections of various floatation devices, but preferably not, inside a tank which should remain hollow for the ingress/egress of air or water. The inclusion of an expanded polymer could allow a thinner base of floatation device, and/or a thinner outer skin of the floatation device to be used and then filled with expanded polymer to provide a more buoyant floatation device.

Thus, there has been provided a floatation device for supporting at least one photovoltaic solar panel above a body of water. Importantly, this allows relatively easy rotation/orientation of solar panels to track the movement of the sun across the sky during the day.

Also advantageously, the floatation devices and solar panels have a cooling effect on the water by shielding the water from solar radiation. It is believed that pockets of cooler air are held under the solar panels which beneficially cools the solar panels as the efficiency of the photovoltaic effect in silicon improves at cooler ambient temperatures.

Moreover, by reducing the level of solar radiation incident on the body of water a reduced evaporation rate of water results. Importantly, this assists to preserve the volume of water by reducing evaporation rates from the water surface. This can be especially important in hot climates where adequate water supply can present a problem and evaporation from bodies of water, for example dams, is sought to be minimised.

According to another aspect a heat sink can be provided. In an optional form, a heat sink can be provided as part of, or attached to, a floatation device or a solar panel. It is believed that the addition of a heat sink, preferably to a rear face of a solar panel, enhances heat dissipation from the solar panel. For example, heat dissipation is enhanced to cooler air above the water shaded by a floatation device and solar panel.

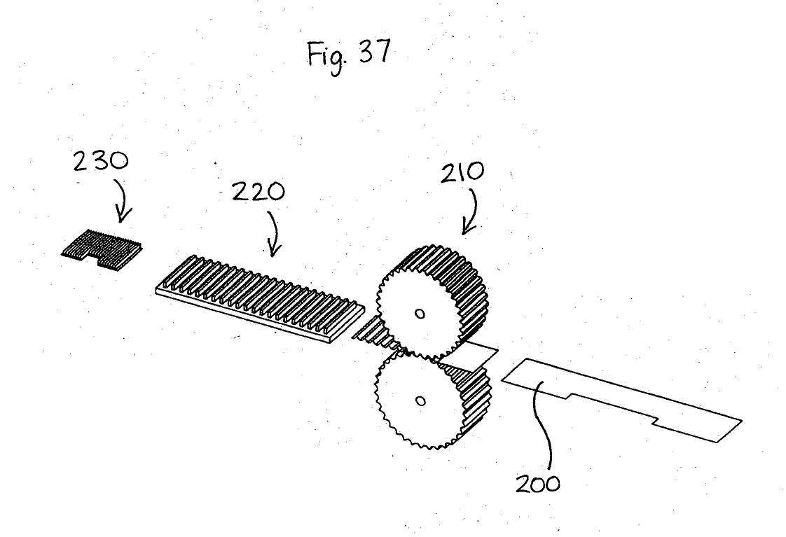

In one example, a heat sink could be produced from folded aluminium foil using a rolling and pressing process. Referring to FIG. 37, there is illustrated an example process for forming a heat sink. A thin metal 200, such as aluminium foil (e.g. 0.1 mm thickness), is passed through rollers 210 to produce a sheet with a corrugated surface. The so-produced corrugated sheet can then be placed adjacent one or more other sheets with cut-out sections. This layered structure can then be pressed, for example using a pneumatic press, to form layered sheet structure 220, which can be further pressed to form heat sink 230 which includes a base section and a plurality of fins. Heat sink 230 can be attached to a rear surface of a solar panel to enhance heat dissipation. A variety of methods or processes can be used to produce a variety of configurations of a heat sink.

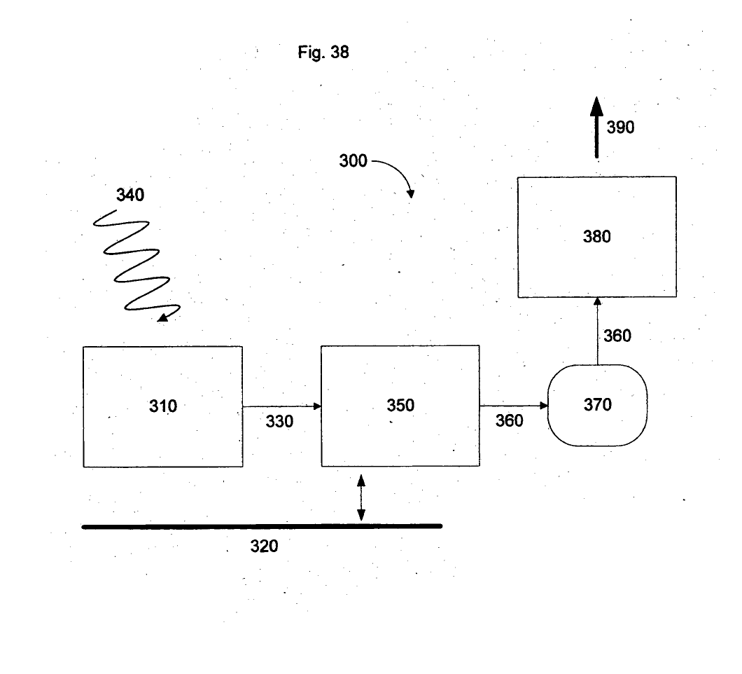

According to another aspect a novel method and system for power generation is provided. Referring to FIG. 38, there is illustrated a system 300 for power generation. An array of solar panels 310, floating on body of water 320 and supported by a plurality of floatation devices, is used to generate electrical power 330, such as DC power, using solar radiation 340, as hereinbefore described. The DC power 330 is then used to run a hydrogen generator 350, which can produce Hydrogen 360, typically in gaseous form, from water 320 using a variety of known water-splitting techniques. This is advantageous as the array of solar panels 310 is already supported above a body of water providing a ready source of water 320 for generation of Hydrogen. The Hydrogen gas 360 can be stored in one or more tanks 370 for on-demand use by an electrical generator 380 that runs on Hydrogen 360, resulting in electrical power (electricity) 390 being generated on an as required basis.

This system can be incorporated into the power grid to supplement current power sources on an as needed basis, or the system could be provided as a stand alone facility, such as for use on private land or for an isolated area, town, industry, etc.

Optional embodiments of the present invention may also be said to broadly consist in the parts, elements and features referred to or indicated herein, individually or collectively, in any or all combinations of two or more of the parts, elements or features, and wherein specific integers are mentioned herein which have known equivalents in the art to which the invention relates, such known equivalents are deemed to be incorporated herein as if individually set forth.

Although a preferred embodiment has been described in detail, it should be understood that many modifications, changes, substitutions or alterations will be apparent to those skilled in the art without departing from the scope of the present invention.

1. (canceled)

2. (canceled)

3. (canceled)

4. (canceled)

5. (canceled)

6. A floatation device for supporting at least one photovoltaic solar panel above a body of water, comprising:
a base able to float on the body of water;
at least one support to position the at least one photovoltaic solar panel at an angle to the base; and,
at least one coupling member used to couple the floatation device to an adjacent floatation device.

7. The floatation device of claim 5, also including at least one further coupling member, formed as a projection from the base.

8. The floatation device of claim 5, wherein the recess or groove is able to couple with an adjacent projection of the adjacent floatation device to form a joint.

9. (canceled)

10. The floatation device of claim 5, wherein a removable linkage member is received in the recess or groove and an adjacent recess or groove of an adjacent base of the adjacent floatation device to form a joint.

11. (canceled)

12. (canceled)

13. The floatation device of claim 1, wherein the at least one support extends from a surface of the base and has a support surface, for supporting the at least one photovoltaic solar panel, that is positioned at an angle in relation to the surface of the base.

14. The floatation device of claim 9, wherein the at least one support is rigid and the angle is fixed.

15. The floatation device of claim 1, wherein the at least one support has a support surface, for supporting the at least one photovoltaic solar panel, that can be positioned at a variable pitch angle in relation to the surface of the base.

16. (canceled)

17. (canceled)

18. The floatation device of claim 1, including a ballast tank or container operable to adjust a base angle of a surface of the base relative to a surface of the body of water, wherein air or liquid is input into or released from the ballast tank or container to adjust the base angle.

19. (canceled)

20. (canceled)

21. The floatation device of claim 13, wherein an arm or pipe extends from the ballast tank or container and through a hole in an adjacent base of an adjacent floatation device.

22. (canceled)

23. The floatation device claim 13, wherein air or liquid can enter or exit an interior region of the base being connected to an interior region of the ballast tank or container.

24. The floatation device of claim 1, including a support structure positioned below the base, wherein the support structure includes a recess or groove extending along at least part of an exterior surface of the support structure for receiving a finger provided as part of an adjacent base of the adjacent floatation device.

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. The floatation device of claim 1, wherein the base includes at least one anchor point to attach a cable, wherein applying a force to the cable causes rotation of the floatation device on the body of water.

37. (canceled)

38. The floatation device of claim 1, including a heat sink positioned at the back of the at least one photovoltaic solar panel.

39. The floatation device of claim 38, wherein the heat sink includes a base section and a plurality of fins.

40. A system for electrical power generation, including:
an array of solar panels supported by a plurality of floatation devices according to claim 1;
a hydrogen generator, to receive electrical power from the array of solar panels, and to use water from the body of water, to produce hydrogen; and
an electrical generator to receive the generated hydrogen and to produce electrical power.

41. (canceled)

42. The floatation device of claim 1, wherein the base includes at least one opening that passes through the base between the body of water and the at least one photovoltaic solar panel.

43. The floatation device of claim 1, wherein each edge of the base has an associated coupling member.

44. The floatation device of claim 1, wherein the base is a hollow body or shell.

45. The floatation device of claim 1, wherein the at least one coupling member is formed as a recess or groove in the base.

46. The floatation device of claim 11, including a tank operable to adjust the pitch angle, wherein air or liquid is input into or released from the tank to adjust the angle.
